(19) United States
(12) Patent Application Publication
(10) Pub. No.: US 2002/0192572 A1
(43) Pub. Date: Dec. 19, 2002

(54) Masks

(76) Inventor: Simon Lau, Nottage (GB)

Correspondence Address: CHRISTOPHER P. MAIORANA, P.C., 24025 GREATER MACK, SUITE 200, ST. CLAIR SHORES, MI, 48080, US

(21) Appl. No.: 10/150,537

(22) Filed: May 17, 2002

Related U.S. Application Data
(63) Continuation of application No. PCT/GB00/04386, filed on Nov. 17, 2000.

(30) Foreign Application Priority Data
Nov. 19, 1999 (GB) 9927285.8
Jun. 30, 2000 (GB) 0015978.0
Aug. 24, 2000 (GB) 0020786.0

(51) Int. Cl. G03F 9/00; B44C 1/22; C25F 3/00; G03B 27/42; G03C 5/00; A47G 35/00

(52) U.S. Cl. 430/5; 428/542.2; 430/322; 216/12; 355/53

(57) ABSTRACT

Printing, marking or etching a surface is achieved using a mask or masks in combination with electromagnetic radiation (such as a laser or the like) or otherwise exposing one or more selected areas of a surface for treatment, utilising transmissive, non-transmissive or modified transmissivity portions of one or more layers of material of the mask. In one embodiment a surface of a first radiation transmissive layer of the mask is partially covered by a second layer of material which is substantially non-transmissive to radiation. An uncovered portion of the transmissive layer is in the shape of an element (such as a character, symbol or shape) to be printed, marked, etched or the like on the surface.

This is a continuation of International Application PCT/GB00/04386, with an international filing date of Nov. 17, 2000 (17.11.00), published in English under PCT Article 21(2). Priority is claimed to Great Britain Application No. 9927285.8, filed Nov. 19, 1999, Great Britain Application No. 0015978.0, filed Jun. 30, 2000 and Great Britain Application No. 0020786.0, filed Aug. 24, 2000.

This invention relates to apparatus for use in applications such as printing, marking or etching a surface, or otherwise exposing one or more selected areas of a surface for treatment, and in particular but not exclusively, to a mask for use in laser printing.

Printing equipment is generally well known and widely available in a variety of types. One known type of printing is laser printing whereby intense laser radiation is directed on to a substrate so as to cause substrate changes such as surface modification, charring, melting, vaporisation, etching or chemical changes causing colour changes. Often, the selection of laser printing over more traditional ink printing techniques such as off-set, inkjet, pad-printing and gravure is due to the permanence of laser produced marks.

Another factor in favour of the laser printing technique is the ability to produce a mark without contact or force so that it is particularly suitable for delicate sensitive substrates or for substrates moving at high production speeds.

Yet another advantage associated with laser printing is the flexibility of laser printing equipment which enables the generation of a variety of characters, numbers, other symbol characters or logos.

One common laser printing technique is often termed a vector scanning technique. In one example of this technique, precision scanning mirrors control the position of the laser spot over an area and in conjunction with a fast controller modulate the laser energy to spatially define a character or logo such that a print is ultimately comprised of many small, laser-produced spots. This technique is also sometimes referred to as dot-matrix printing. Alternatively, the same effect can be achieved by fixing the beam spot stationary and instead, moving the substrate along vectors or from point to point using for example, a two-axis motion stage.

Whether the beam is fixed or scanning, this technique is extremely flexible and uses no hard tooling. In production this high flexibility is an advantage and can be used for printing batch sizes of one. The disadvantage is that specialist knowledge is required to set-up, service and support the high speed electronics and precision, low inertia, high speed optics.

Additionally, in production, batch sizes of one are not common and so vector scanning solutions might be considered as an over-engineered, over specified technological solution in many circumstances.

Because the character produced by the above-described technique is formed from many dots, the character printing speed is relatively low. One can increase the printing speed by reducing the resolution of dots although this has an adverse effect on character quality or legibility.

Another commonly employed laser printing technique is most often termed mask imaging whereby a stencil is used as a mask to spatially profile the raw laser beam to the desired shape of the character, letter or logo. Often the mask is a chemically etched metallic sheet. For example, a stainless steel disc is chemically etched with the ASCII character set and rotated through a laser beam. The rotational motion through a laser beam is synchronised by a controller. At a synchronised instant, the controller positions the desired character in the beam path and the raw laser beam, usually in the shape of a circle, impinges on the chemically etched character. Where the metal has been fully etched away, the laser beam propagates to the substrate that is to be printed upon. Where the metal is still intact, the beam reflects back unused. In this way a single laser shot forms a complete character.

The above-described technique, whereby whole characters are printed at a time, is a high speed printing technique but it has the disadvantage that it is necessary to use a stencil tool, which is not easily changed if a new logo or new font set is required. It is therefore suitable for large batch sizes where the marked information is not changed regularly. As with vector scanning technology, the level of specialist support required is considerable, which is a disadvantage of laser printing generally compared to the more traditional ink printing technologies.

In addition, the construction of a stencil is not straightforward. During manufacture, thin tags must remain to support the centres of certain letters such as a,A,b,B,d,D,e etc. to restrict the laser beam to an outline or stroke rather than a filled letter. Insertion of thin tags into pictures or logos can be extremely difficult, and in some instances impossible.

Further, the tags must be as thin as possible so that the printed characters are not visually detrimentally affected by the presence of the tags. However, since the masks are often rotated at high speed, the tags in the stencil need to be of a certain minimum thickness to provide enough strength to hold the central body of the character in place. Thus, a trade-off situation is presented because to prevent destruction of the stencil masks caused by breaking masks at the tag points (which must be thin enough to prevent visually detrimental effect on the printed character)requires the speed of rotation to be limited, thereby limiting the printing speed.

Consequently, and in summary, there is a need for a laser printing technique which has increased flexibility similar to that of vector scanning technology, but has increased printing speed similar to that of a stencil mask technique, and avoids the need for tags. It is also desirable for the apparatus for performing the technique to be of simple construction without the need for high speed electronics or high performance optics.

Accordingly, we have now devised an arrangement which seeks to solve the above-mentioned problems and provides high print flexibility without detrimental tags at high speed.

In accordance with a first aspect of the present invention, there is provided a mask for printing, marking or etching a surface using electromagnetic radiation, such as a laser or the like, or otherwise exposing one or more selected areas of a surface for treatment, the mask comprising a first layer of substantially radiation transmissive material and a second layer of material which is substantially non-transmissive to radiation, said non-transmissive layer being applied on or joined to said transmissive layer so as to partially cover a surface thereof, an uncovered portion of said transmissive layer being in the shape of an element, such as a character, symbol or shape, to be printed, marked, etched or otherwise provided on the said surface.

The transmissive layer is beneficially substantially transparent, and may comprise a printer transparency, typically of polyester film, polythene film or other plastics film, or an acetate or cellulose film or the like.

The mask may be in the form of a rotatable disc of transmissive material with the non-transmissive material being applied thereon or joined thereto so as to partially cover the surface thereof, a plurality of uncovered portions of the transmissive layer being in the shape of elements to be printed, marked or etched on the surface. In this case, the uncovered portions are beneficially located at, or adjacent to the circumference of the disc. Alternatively, the mark may be generally ring-shaped, or even an elongate strip having along its length a plurality of uncovered portions in the shape of elements to be printed, marked or etched on the surface.

The non-transmissive layer may be an absorbing or reflecting material, such as ink or toner, selectively applied to the transmissive layer. Alternatively, the non transmissive layer may be a sheet of absorbing or reflecting material, such as paper, bonded to the transmissive layer.

According to a second aspect of the present invention, there is provided a mask for printing, etching or marking a surface using electromagnetic radiation, such as a laser or the like, or otherwise exposing one or more selected areas of a surface for treatment, the mask comprising a first layer of substantially clear or transparent material and a second layer of material which is substantially non-transmissive to radiation, said non-transmissive layer having a substantially transmissive portion in the shape of an element, such as a shape, character or symbol to be printed, etched, marked or otherwise provided on the said surface.

In this case, the transmissive and non-transmissive layer may be in contact or in very close proximity with each other, when in use. Alternatively, the transmissive and non-transmissive layers may be spatially separated from each other, when in use.

Once again, the transmissive material may comprise a printer transparency or acetate or cellulose film. The non-transmissive layer may be an absorbing or a reflecting material, such as ink or toner, selectively applied to said transmissive layer, alternatively, the non-transmissive layer may be a sheet of absorbing or reflecting material, such as paper.

In accordance with a third aspect of the invention, there is provided a mask for printing, etching or marking a surface using electromagnetic radiation, such as a laser or the like, or otherwise exposing one or more selected areas for treatment, the mask comprising a first layer of substantially radiation transmissive material, and a second layer comprising at least two portions which are transmissive to radiation, one of said radiation transmissive portions being relatively less transmissive to radiation than the other portion.

The second layer may be made up of one or more coloured inks or toners selectively applied to the first layer. In fact, the second layer beneficially comprises a plurality of portions of varying degrees of transmissivity.

Full tone greyscale printing is desirable in some instances to create shades or tones not interleaved with white spaces.

The conventional vector scanning printing technique can be used to create half-tones whereby the density of laser dots is changed so that the eye views an area comprised of a varying number of white spaces and black dots. When the dots are printed finely the eye perceives a grey rather than the actual mixture of white spaces and black dots. Vector scanning can therefore be considered as a digital printing technique whereby a dot is either present or not, caused by the laser beam being present or not. It is conceivably possible to create true greyscales using the vector scanning technique by modulating the energy of the laser on a shot-by-shot basis, thereby creating dots of different contrast. However, practically, the laser energy of a laser printing system is constant and stable and a function of the thermal environment of the laser pumping chamber having a long time scale compared to the time interval between successive laser shots.

Mask imaging using stencil masks is also a digital technique whereby the laser energy beam is either present or not, determined by whether the mask is “open” or solid. It is conceivably possible that the spatial distribution across a laser beam can be controlled though this is not possible on a shot by shot basis or indeed, in a controlled fashion.

In the case of the mask of the third aspect of the invention, the deposition of reflective or absorptive layers can be controlled. For example, black ink is a highly absorptive layer which restricts or prevents laser beam transmission. However, using coloured inks such as red, orange, green and blue has a different effect on laser beam transmission. For example, a green ink with a green laser wavelength creates a reflective ink. Different shades of green reflect the laser light by different amounts. Different colours and different shades of colours alter the transmission of the laser beam through the laminate mask. The propagating laser beam can therefore be modulated in energy resulting in a different marking contrast. Therefore, using a laminate mask comprising different coloured inks or different shades of colours creates a laser mark on the substrate showing true continuous greyscales. The mask of the third aspect of the invention can therefore be used within an analogue printing technique, which may be achieved with 355 nm laser radiation.

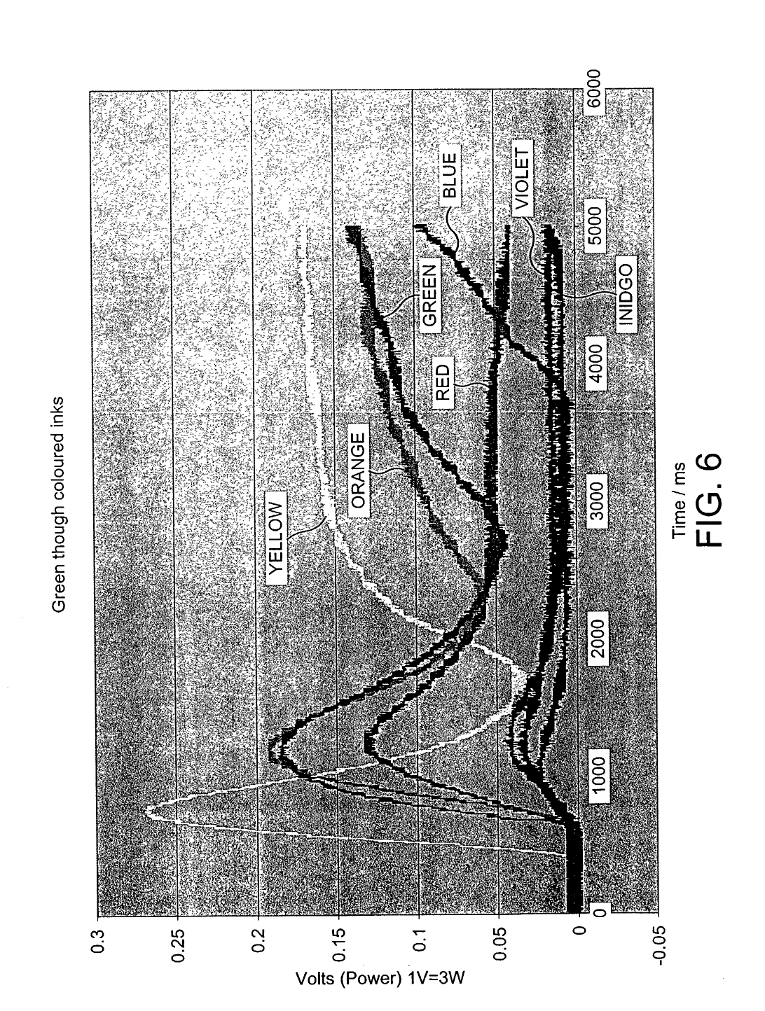

FIG. 6 shows the different laser beam transmission levels for various types (colours) of the second layer (the ink layer)

The mask of the third aspect of the invention can be used for printing pictures, logos and also text in differing contrasts. The mask spatially modulates the laser energy propagating to the sample surface while the laser provides a stable, constant output.

As well as laser printing pictures, the mask can be used in a new way for storing information. For example linear bar codes are being replaced by two-dimensional bar codes such as PDF 417 and Data Matrix. The attraction with these two-dimensional bar codes is the fact that information-storing ability is greatly increased per unit area. However all two-dimensional bar codes are created using digital printing techniques. If an analogue printing technique was used instead then a two-dimensional bar code could be created with the ability to print tones as well. In effect the laminate mask allows the printing of three-dimensional bar codes, the third dimension being contrast. Each point in a matrix now has three attributes x, y and contrast, or greyscale. This additional dimension can be used to increase data storage capability or to decrease the area required to store a given amount of data compared to one or two-dimensional bar codes.

In accordance with a fourth aspect of the invention, there is provided a mask for printing, etching or marking a surface using electromagnetic radiation such as laser or the like, or otherwise exposing one or more selected areas of a surface for treatment, the mask comprising a layer of substantially radiation transmissive material, a portion of which has been subjected to spatial modification to reduce the transmissivity thereof.

Also in accordance with the fourth aspect of the invention, there is provided a method of making a mask for printing, etching or marking a surface using electromagnetic radiation such as a laser or the like, or otherwise exposing one or more selected areas of a surface for treatment, the method comprising the steps of spatially modifying a portion of a layer of substantially radiation transmissive material to reduce the transmissivity thereof.

The spatial modification is beneficially achieved by prolonged exposure to electromagnetic radiation, such as a laser, so that a portion of the incident radiation is absorbed by the transmissive material, creating a physical change in the properties of the layer.

One of the advantages of the mask of all aspects of the invention and the associated printing technique is that characters can be created without the use of tags. With stencil masks, tags must be used to hold the central parts of characters in place. However, the added advantage of the mask of the fourth aspect of the invention is that it is comprised of a single layer.

In the method of the fourth aspect of the invention, the transmissive layer is modified spatially so that the transmission properties of certain regions are changed, for example to become non-transmissive by increasing the absorption coefficient of the transmissive layer.

This can be achieved using a laser such as a modulated continuous wave IR laser or a short-pulsed IR, UV or visible laser. Though the “transmissive” layer is nominally transmissive, if the exposure duration is prolonged, or the intensity of the laser is increased, a fraction of the incident laser energy is actually absorbed by the transmissive layer. This absorption of laser energy creates a physical change in the properties of the layer and the substrate is observed to “brown”, that is change from being clear to exhibiting a hazy colour, normally yellow or brown. With over exposure, melting and eventually vaporisation occurs.

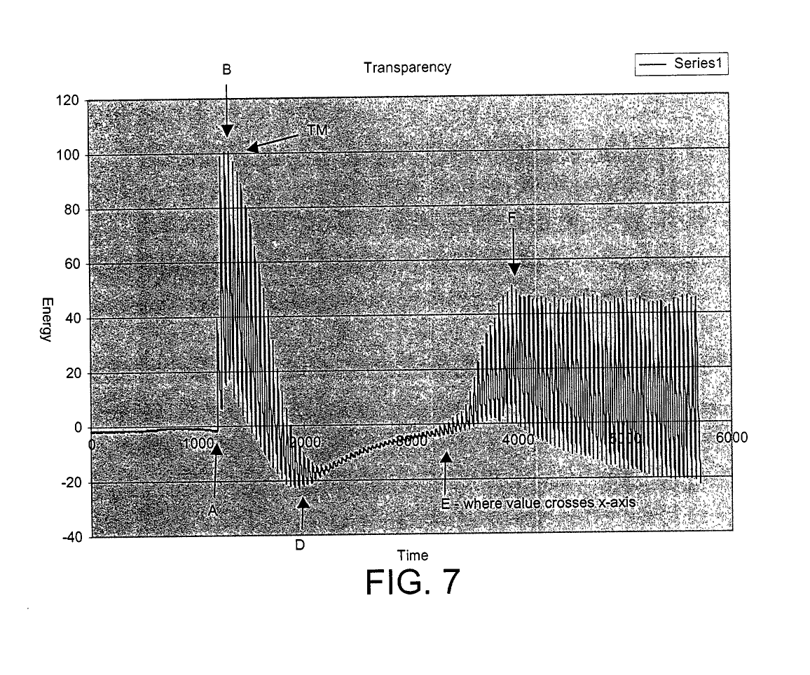

FIG. 7 shows the transition from originally transmissive to decreasing transmission as the transmissive layer browns, to transmissive again as eventually the laser drills through the layer. Therefore, controlled exposure of the laser can be used to change the transmissive properties of the transmissive layer thereby removing the need for the addition of the second non-transmissive layer used in the first, second and third aspects of the invention. Since the laser is controlled to change the properties of discrete regions whilst keeping the layer as a single, continuous sheet, there is no necessity to use tags.

In one specific embodiment, this can be achieved by using a pulsed Nd:YAG operating at 50-60 mJ per pulse, repetition rate of 25 Hz, pulse lengths of approximately 5 ns and wavelengths of 355 nm and 532 nm. It is envisaged that focussed cw IR lasers can be used to achieve the same result.

In the case of the first, second, third and fourth aspects of the present invention, the element to be printed, marked or etched on the surface, or the area of the surface to be exposed, may be one or more of graphics, alphanumeric characters, symbols, patterns, numbers and pictographic symbols.

The invention extends to apparatus for printing, etching or marking a surface, or otherwise exposing one or more selected areas of a surface for treatment, the apparatus including a mask according to any one of the first, second, third or fourth aspects of the present invention. In this case, the apparatus preferably includes a source of electromagnetic radiation, such as a laser. The laser may be a frequency-tripled Nd:YAG laser. The laser is beneficially pulsed.

In one example the laser may be actuated in pulses of around 5 ns, at a pulse repetition frequency of around 25 Hz and a pulse energy of around 50 mJ.

In the case where the mask is in the shape of a disc (which may apply to any one of the four aspects of the invention) the apparatus beneficially includes a circular, rotatable table for receiving objects to be printed, marked or etched, the mask being rotatable and positioned between the table and the source of electromagnetic radiation, when in use.

In the case where the mask is generally ring-shaped or in the form of a continuous closed loop (which, once again may apply to any one of the four aspects of the invention), the mask is preferably rotatable and the source of electromagnetic radiation is preferably located within the ring-like mask, with the objects to be printed, etched or marked being located outside the ring-like mask, such that, in use, the mask is between the source of electromagnetic radiation and the object.

In the case where the mask is an elongate strip, the mask is preferably wound on a first spool, and the apparatus includes a second spool, the mask being fed, in use, between objects to be printed and the source of electromagnetic radiation from the first spool to the second spool.

In all cases, the apparatus may include beam expansion optics, such as a telescope or diverging optical lens, located between the source of the electromagnetic radiation and the mask.

In accordance with a fifth aspect of the present invention, there is provided a method of making a mask for use in printing, marking or etching a surface using electromagnetic radiation, or otherwise exposing one or more selected areas of a surface for treatment, the method comprising the steps of providing a first layer of substantially radiation-transmissive material and applying thereon or joining thereto a second layer of material which is substantially non-transmissive to radiation, such that said non-transmissive layer partially covers said transmissive layer, an uncovered portion of said transmissive layer being in the shape of an element, such as a shape, character or symbol to be printed, marked etched, or otherwise provided on the surface. The transmissive layer is beneficially substantially transparent, and may comprise a printer transparency typically of polyester film, polythene film or other plastics film, or an acetate or cellulose film. The non-transmissive layer is beneficially printed onto the transmissive layer, in which case the non-transmissive layer may be ink or toner applied to the surface of the transmissive layer.

The method of the fifth aspect of the invention may include the step of at least partially covering a sample to be printed with a substantially transparent packaging film, and then applying the non-transmissive layer to said packaging film, such that said packing film is effectively the transmissive layer of the mask. Alternatively, the method may include the steps of applying the non-transmissive layer to a transparent packaging film before at least partially wrapping the packaging film around an object, the surface of which is to be printed, marked or etched, such that once again the packaging film effectively forms the mask.

The method of the fifth aspect of the invention, may include the step of bonding or otherwise joining a sheet of absorbing or reflecting material, which has a transmissive portion in the shape of the element to be printed, marked or etched, to the transmissive layer. In this case, the absorbing or reflecting material may be paper.

In one embodiment, the transmissive portion of the non-transmissive material may be formed using a laser cutter prior to bonding or joining to the transmissive layer. Alternatively, the non-transmissive material may first be joined or applied to the transmissive layer, and a portion thereof subsequently removed to form the transmissive portion in the shape of the element to be printed. This may be done using a laser etching system.

Alternatively, one or more sheets of transmissive material may be selectively printed automatically by an ink or toner cartridge mounted on a belt or carriage powered by a motor for movement across the paper plane, in a similar manner to that in which paper is printed by a conventional printer and, in fact, a conventional printed, such as Lexmark 1100, Brother HL-1070 or a Lexmark Z11, can be used as a framework. Means such as a mirror for directing a beam of electromagnetic radiation onto the masks after printing, in which case, samples to be printed may also be carried in the apparatus, underneath the masks. The samples and transmissive sheets may be carried on a belt travelling transverse to, or in the opposite direction to the ink or toner cartridge. As the cartridge and the belt move along their transverse or opposite directions, the masks are printed and the electromagnetic radiation (located behind the ink or toner cartridge relative to the direction of travel of the cartridge) is subsequently applied to the samples through the printed mask to mark, print or etch the samples, as required.

Thus one embodiment of the invention employs a laminate mask for laser printing which may be manufactured from a transmissive laminate or layer supporting an absorbing or reflecting laminate or layer. However, the non-transmissive laminate or layer is selectively applied so that laser light transmission through the laminate mask is confined to the inverse or negative pattern of the non-transmissive laminate. It should be noted that in this specification, the terms transmissive and non-transmissive refer to the optical properties of the laminates or layers at the laser wavelength employed. The laminate mask forms a two dimensional area with the transmissive laminate supporting the non-transmissive laminate from one face or the opposite face. Since the support of the non-transmissive laminate is in a direction towards the supporting laminate, that is, in the direction of light propagation, the need for tags is eliminated.

In the above-described embodiment, the laminate mask is positioned in the beam such that the raw laser beam impinges on the laminate mask. Those parts of the beam that impinge on the transmissive laminate that is not additionally patterned by the non-transmissive laminate continue unaffected, whereas the parts of the beam that are blocked by the patterned non-transmissive layer are reflected back or absorbed by the non-transmissive laminate. In this way the laminate mask spatially profiles the raw laser beam to the shape of the inverse or negative patterned, non-transmissive laminate which could be a tagless character or logo. The profiled laser beam propagates to the substrate and laser printing of the desired pattern occurs. Note that in this specification, transmission and non-transmission need not be one hundred percent, but such that a large enough differential exists so that the patterning created by the laser on the substrate is visually satisfactorily perceptible, according to requirements.

The laminate mask may be in contact or very close proximity with the substrate in which case the laminate mask would be termed a contact laminate mask or a conformal laminate mask. Alternatively the laminate mask would be spatially separate from the substrate and using an optical lens or other optical element the pattern produced on the laminate would be imaged into the substrate in which case the laminate mask would be termed an imaging laminate mask.

For printing of extended areas larger than the laser beam size, the laminate and substrate can be moved together, relative to the laser beam. Alternatively, the laminate and substrate can be stationary with the laser beam rastering across the laminate mask.

A primary disadvantage of the stencil mask used in the conventional mask imaging technique described above is that the mask must be moved at high speed between laser pulses so that on the following laser pulse the mask is accurately positioned with the desired character precisely in the beam path. The character or data string is thus created pulse by pulse. Additionally, an imaging optic and normally several other optics must be used, whose positions relative to the mask and target material need to be precisely controlled. In view of the separations involved, there is a large space envelope requirement.

Furthermore, specialist components, such as scanning or rotating precision mirrors, precision optics, mask and laser-associated electronics, are all required to work in unison to tight tolerances in order to ensure that the laser pulse, the mask, the tracking mirrors and the substrate are spatially and temporally matched.

In summary, therefore, the design and complexity of the equipment is such that these systems are limited to very few applications. An example of one use of this technique is for applying circuit codes to insulated, electrical wires.

Where the character or data string is limited in size to just several characters such as date or batch codes, a simpler configuration can be used whereby a larger beam and larger mask are employed, and with a single exposure of the beam the whole string is printed. In this case the mask is stationary and timing is less critical. However, a severe disadvantage is that a laser is required that can provide sufficient energy to illuminate the whole of the data string simultaneously. As the data string grows, the area of illumination therefore grows (if maintaining a constant and visually useful character size) and the laser energy must increase proportionally to the square of the unit length increase. This configuration is therefore limited to short data strings. The high cost and low availability of high-energy lasers for this large area illumination mean that such a multi-character mask imaging configuration is limited to just a few practical applications.

As explained above, with the conventional vector scanning/dot matrix printing technique, low energy lasers direct beam pulses to a substrate and a character is constructed by many laser spots. Usually, the beam is spatially directed across the material to construct characters or symbols, while the material moves along a production line.

Disadvantages of this technique are that high repetition rate lasers are required to support factory line speeds. To increase printing speed, a common compromise is to mark fewer spots per character but these low resolution characters detrimentally affect legibility of the marking. The cost and performance of these lasers limit the usefulness of this technique.

The object of the sixth aspect of this invention is to provide a marking or other surface treatment technique that is simple in design and can create fully formed legible markings for short, medium or long data strings without the need for high speed scanning optics, precise timing electronics, a precision rotating mask, high rep rate lasers, or high energy lasers.

In accordance with the sixth aspect of the present invention, there is provided a mask for use in printing, marking or etching a surface using electromagnetic radiation, or otherwise exposing one or more selected areas of a surface for treatment, the mask being in the form of a continuous closed loop, such as an annular or hollow cylindrical body.

The mask preferably comprises a first layer of substantially radiation transmissive material and a second layer of material which is substantially non-transmissive to radiation, said non-transmissive layer being applied on or bonded to the transmissive layer so as to partially cover a surface thereof, an uncovered portion of the transmissive layer providing a window in the shape of an element, such as a character, symbol or shape, to be printed, marked or etched on the surface.

The mask preferably has a central axis, about which it can be rotated.

The sixth aspect of the invention extends to apparatus for printing, marking or etching a surface, or otherwise exposing one or more selected areas of a surface for treatment, the apparatus comprising a mask as defined above, means for rotating the mask, support means for supporting an object to be printed, marked or etched, and means for directing electromagnetic radiation through the mask and onto the surface of the object to be printed, marked or etched when the object is supported by the support means.

Such printing, masking, etching or other treatment will be referred to hereinafter as “marking”.

The electromagnetic radiation preferably comprises laser radiation, and the apparatus beneficially comprises a beam-turning optical element, such as a mirror, arranged to direct the laser through the mask and onto the surface of the object to be marked.

The apparatus preferably includes transport means for transporting one or more objects to be marked to a position in which said marking is to take place, and means for synchronising movement of the transporting means with rotation of the mask. Preferably the transport means (e.g. a production line or the like) is linked to the mask via a mechanical linkage such as gears, cogs, belts or chains, or the like. In another embodiment of the invention, an electronic servo-driven (or similar) linkage may be used. Alternatively, the mask may be a rotating mechanism in contact with the production line or web material.

The sixth aspect of the invention further extends to a method for marking, or otherwise treating a surface, the method comprising the steps of providing a mask, rotating the mask, and directing electromagnetic radiation through the mask onto the surface to be marked.

In accordance with a seventh aspect of the present invention, there is provided apparatus for printing, marking or etching a surface, the apparatus comprising a mask, means for transporting one or more objects to be printed on, marked or etched to a position in which said printing, marking or etching is to take place, means for moving the mask in synchronism with said transport means, and means for directing electromagnetic radiation through the mask and onto the surface of the object to be printed on, marked or etched at said position in which said printing, marking or etching is to take place.

Also in accordance with the seventh aspect of the invention, there is provided a method of printing, marking or etching a surface, the method comprising the steps of providing a mask, transporting one or more objects to be printed on, marked or etched to a position in which said printing, marking or etching is to take place, moving said mask in synchronism with the objects being transported, and directing electromagnetic radiation through the mask and onto the surface of the object to be printed on, marked or etched at said position in which said printing, marking or etching is to take place.

In this case, the mask may be in accordance with the sixth aspect of the invention, i.e. in the form of a continuous, closed loop. Alternatively, the mask may be in the form of an elongate tape moving in synchronism with the transport means, for example, between two spools or the like.

Additionally, the method and apparatus of the seventh aspect of the invention may include any one or more of the preferred features mentioned above with reference to the sixth aspect of the invention.

As the mask is not optically imaged, there are no critical separation distances and so the laser, the electromagnetic radiation beam, the beam turning optic, the mask and the material to be marked can be placed close to one another, reducing the occupying volume and dimensions of apparatus including the mask.

It will be appreciated that the mask defined in accordance with various aspects of the invention can be used in many different applications where it is required to expose selected areas of a surface for treatment. In addition to marking or printing on a very wide range of different plastics, the mask could be used to harden resins or in rapid prototyping whereby a laser (or other electromagnetic radiation) is used to cure or set a resin, or set a liquid plastic to solid plastic, in specific sites exposed by the mask, or similarly to cure UV curable inks, whereby upon exposure to UV radiation (as permitted by the mask) the ink is cured and the remaining ink (not exposed to the UV radiation by the mask) can be washed off to leave a pattern of coloured ink.

The mask could also be used in stereo lithography or in production of printed circuits or in semiconductor photolithography by the mask (causing a chemical reaction in those areas) prior to chemical etching. Similarly, it could be used as a resist in electrochemical machining techniques.

Other potential applications include selective exposure of surfaces to be bleached or to produce some other chemical or physical change thereto, selective vulcanisation of rubber, biological sterilisation of array pieces (exposure of selected areas of an array piece to intense UV radiation in order to kill bacteria), and driving chemical reactions in selected areas of prepared planar surfaces, including generic chemical reactions and, for example, titanium dioxide state changes.

Exemplary embodiments of various aspects of the present invention will now be described with reference to the accompanying drawings, in which:

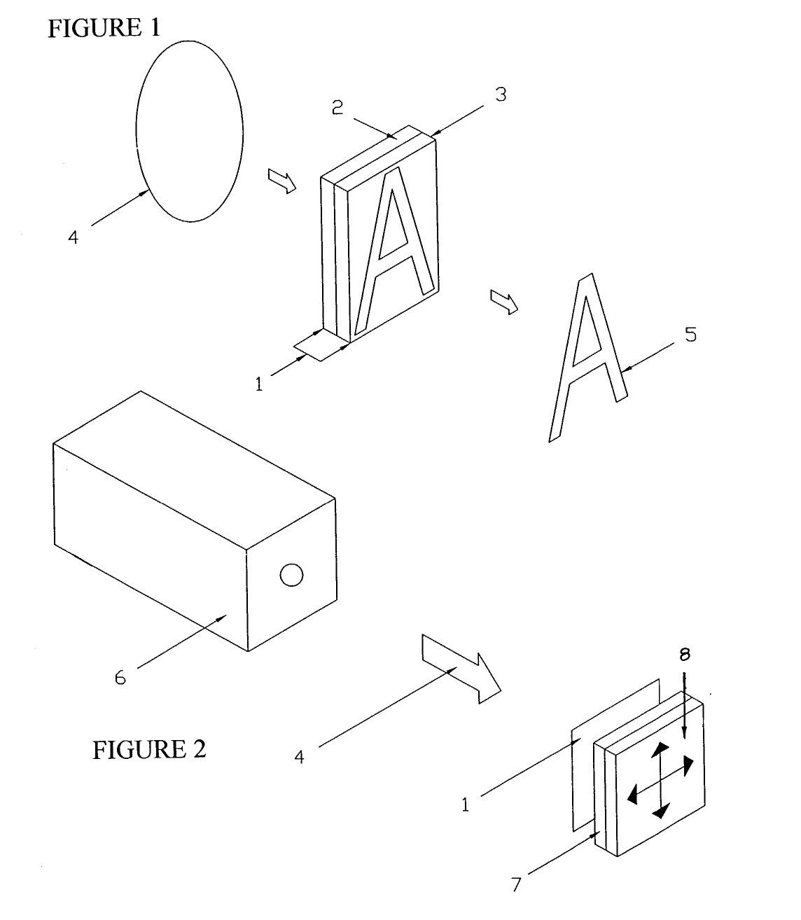

FIG. 1 is a schematic diagram of the construction of a laminate mask, according to one exemplary embodiment of the invention;

FIG. 2 is a schematic diagram of how the laminate mask of FIG. 1 can be employed as part of a laser printing system;

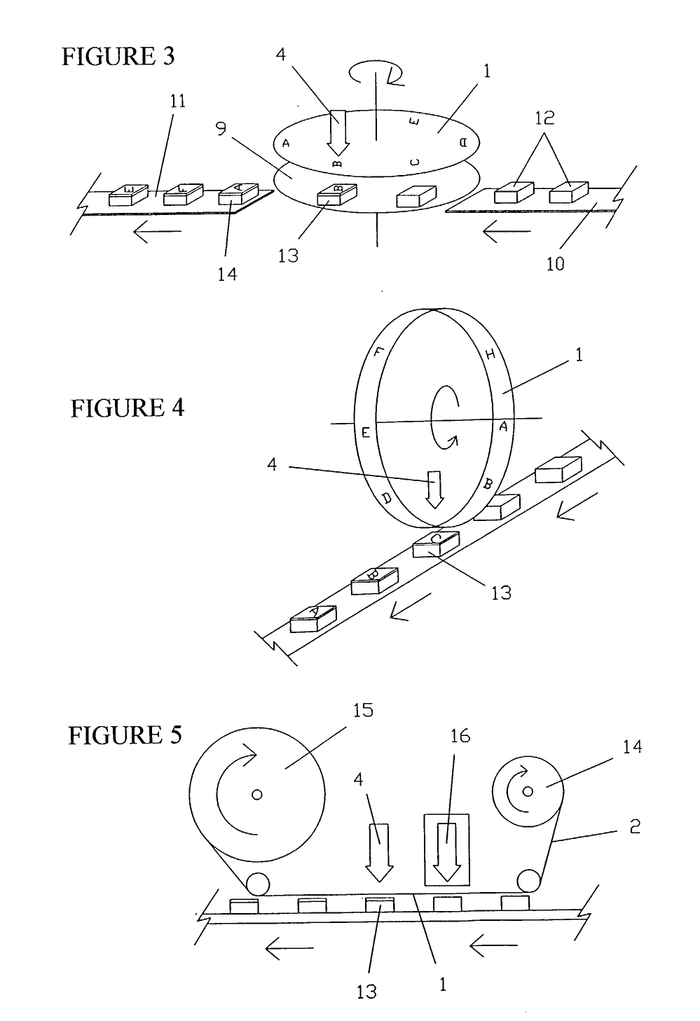

FIG. 3 is a schematic diagram of laser printing apparatus according to a second exemplary embodiment of the invention;

FIG. 4 is a schematic diagram of laser printing apparatus according to a third exemplary embodiment of the invention; and

FIG. 5 is a schematic diagram of apparatus for making a mask according to an embodiment of the invention.

FIG. 6 is a graph showing different laser beam transmission levels for various colours of non-transmissive layer;

FIG. 7 is a graph showing the transition from originally transmissive to relatively less transmissive and back to transmissive during spatial modification of transmissive layer;

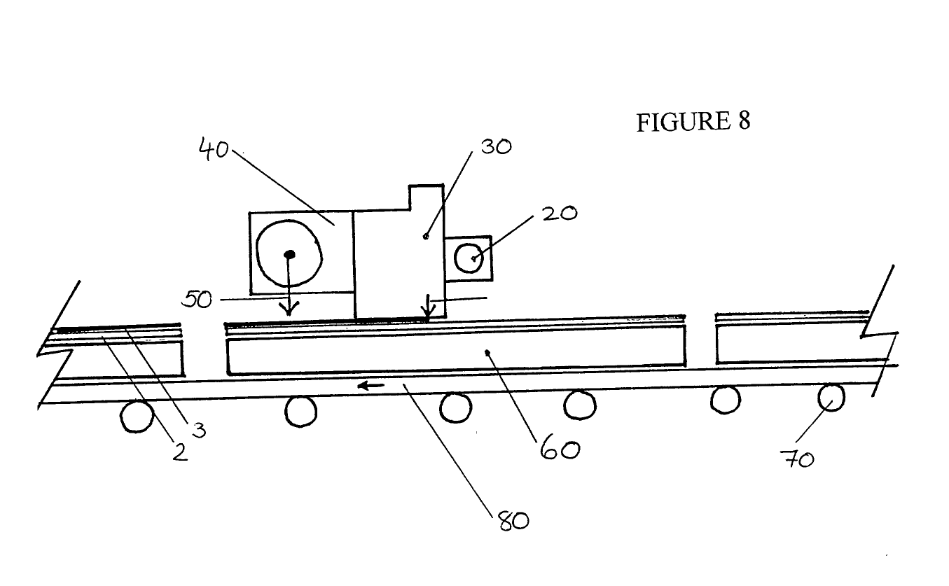

FIG. 8 is a schematic diagram of an exemplary embodiment of apparatus for making a mask according to the invention and for making, printing or etching a surface using said mask;

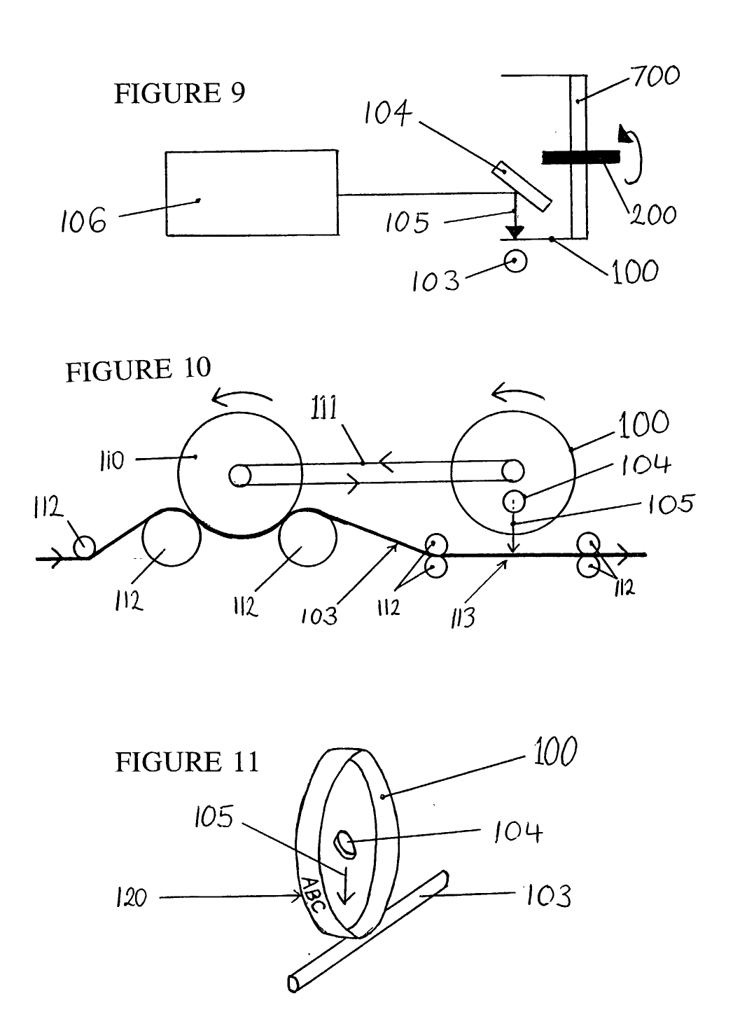

FIG. 9 is a schematic side view of marking apparatus according to an exemplary embodiment of the invention;

FIG. 10 is a front view of the apparatus of FIG. 9; and

FIG. 11 is an example of an annular mask according to an exemplary embodiment of the invention.

With reference to FIG. 1 an exemplary embodiment of a mask 1, comprising a transmissive laminate 2, supporting a non-transmissive laminate 3. The non-transmissive laminate 3 according to the invention is inversely or negatively patterned in the shape of a letter “A” without tags and positioned such that an incident laser beam 4 interacts with the laminate mask to allow only propagation of the spatially patterned laser beam 5 now in the shape of the letter “A” on to the substrate (not shown).

The laminate mask 1 can alternatively be orientated through one hundred and eighty degrees such that the laser beam 4 is first incident on the non-transmissive laminate 3 and then propagates through the transmissive laminate 2.

With reference to FIG. 2 there is shown an example of how the laminate mask of FIG. 1 can be used to laser print a sample. The laser device 6 fires a laser beam 4 onto the laminate mask 1 and the transmitted beam is incident on the sample 7 thus creating a permanent laser mark. Motion control apparatus 8 is provided which is able to move the sample and laminate mask through the beam to build up a pattern on the sample, which could be larger than the size of the raw laser beam and in fact as large as the laminate mask.

One exemplary embodiment of the invention may be used to laser print plastic chopsticks with permanent decorative or advertising information or other patterns. A frequency-tripled Nd:YAG laser operating at a wavelength of 355 nm may be used to laser print plastic chopsticks with advertising information in the form of English alphanumeric characters in a variety of font styles and sizes and Chinese characters in a variety of font styles and sizes. The laser pulses from the Nd:YAG laser may be approximately 5 ns in duration, the pulse energy may be approximately 50 mJ and the pulse repetition frequency may be 25 Hz. It is envisaged, however, that a much wider range of wavelengths can be used, particularly in the visible and near UV spectrum, depending on the optical transmission properties of the laminate mask. It is also envisaged that a range of pulse durations, pulse energies and repetition rates can be successfully employed. It is further envisaged that other laser devices may be used such as Neodynium glass lasers, other solid state lasers and gas lasers.

Referring to FIG. 2 the laser pulses 4 from the frequency-triple Nd:YAG laser 6 are directed onto a laminate mask 1. The laminate mask may be laying in close proximity to the plastic chopsticks 7 and therefore used as a contact laminate mask. The plastic chopsticks and the laminate mask are moved across the stationary laser beam in two axes using a motion stage 8, for example, a servo driven XY stage.

The laminate mask may be manufactured by ink printing a standard A4 transparency using a known personal computer or the like, and a known desk-top ink printer or the like. The printer used to pattern the ink onto the transparencies may be a Lexmark type 1100 and the ink may be from a Black Lexmark cartridge type 1380620, a Colour Lexmark cartridge type 1380619, or in fact any suitable ink may be used.

Alternatively, the transparency may be patterned using a laser printer such as the Brother HL-1070 with toner cartridge TN-300. Alternatively, photocopiers with copy/print cartridges, such as the Xerox 113R276 toner, can be used to produce the laminate mask.

The A4 transparency may be an Epson Inkjet transparency type S041063 or a Hewlett Packard Premium Inkjet transparency film type HP C3832A. Alternatively transparencies for laser printers or photocopiers can be used. It is expected that transparencies from other manufacturers can be used. It is expected that transparencies of different sizes can be used. It is expected that acetate film or cellulose film or other clear film transparencies can be used.

A variety of graphics, alphanumeric characters, symbols and patterns can be printed in a variety of sizes, shapes and fonts. Pictographic symbols, such as Chinese characters and Cyrillic characters can be printed.

The deposition of ink into the desired pattern during printing of the transparencies is one example of a non-transmissive laminate 3. The transparency itself is one example of a transmissive laminate 2. The finished, printed transparency comprising the ink deposited into the transparency is an exemplary embodiment of a mask according to the invention.

It is envisaged that many different products can be marked in this way particularly plastic products such as electrical switches, plugs and sockets, other electrical components, plastic containers such as food storage containers, plastic spoons etc.

The XY motion stage 8 is used to move the laminate mask 1 and the chopsticks 7 through the fixed beam 4. In this instance a standard servo-driven stage can be used. In this example, the speed of the stage in the X and Y directions may be such that overlapping of laser shots occurs. The degree of overlap can be varied using the motion controller to alter the amount of exposure of the substrate thereby altering the contrast of the printed marks.

In a further example, a diverging optical lens may be used between the laser and the laminate mask. The lens diverges the laser beam thus allowing a greater coverage of the laminate mask for each laser pulse. This increases the printing speed of this technique. Alternatively other beam expansion optics such as telescopes can be used to enlarge the beam spot, also allowing an increase in printing speed. In particular, the laser directed onto the laminate mask and the laminate mask may be distanced around 500 mm from the substrate. A plano-convex lens can be inserted at a particular point between the laminate mask and the substrate. In this case, the laminate mask used as an imaging laminate mask and the patterning on the laminate mask provided by the ink on the transparency is demagnified and projected onto the substrate, such as an electrical switch made from polycarbonate plastic.

The printing apparatus of the present invention may be adapted to laser print patterns onto a series of samples. For example, and referring to FIG. 3, an exemplary embodiment of such printing apparatus comprises a circular table 9 having an input feed 10 and an output feed 11. Samples to be printed 12 are fed via the input feed and rotated around the circular table under the printing area 13 where the laser beam 4 is directed. The marked samples 14 exit the apparatus at the output feed after having been laser printed. Rotating above the samples is a patterned laminate mask 1 in the shape of a disc, and the position of the patterns are synchronised with the position of the samples. Therefore, a series of samples can be laser printed using a rotating laminate mask.

Alternatively, in another exemplary embodiment of the invention, referring to FIG. 4 of the drawings, the laminate mask 1 is formed as a rotating ring and the rotational speed of the laminate mask is synchronised with the production line speed, such that the patterning of the laminate mask is positionally matched with the location of the products to be printed 12 at the printing area 13. The laser beam 4 is spatially profiled by the laminate mask. In this case, the laminate mask is preferably not made from a standard A4 transparency, but from a suitable transparent material such as acetate which would provide the support for the non-transmissive laminate.

In yet another exemplary embodiment of the invention, the laminate mask is fed from a feed spool through the laser beam and on to a take up spool. The feed speed of the laminate mask is substantially synchronised to the line speed of the product carrying production line such that the pattern profiled laser beam laser prints the products as they pass beneath the laminate mask. The feed spool may contain a pre-patterned laminate mask. To optimise coverage of the laser beam, optics may be employed to form a line focus, in a direction across the laminate mask.

However, as shown in FIG. 5, means may be provided to pattern the transmissive laminate as required by the production line. The feed spool 14 contains the transmissive laminate 2 only, in the form of a transparent film such as an acetate film and a patterning device 16 such as an ink printing device deposits the ink in the inverse or negative pattern desired to produce the non-transmissive laminate layer of the laminate mask 1. The location of the patterning device is beneficially between the feed spool and the laser printing area 13 and the patterning device is programmed to form the pattern desired in synchronisation with the products on the production line. The laser beam may be formed as a line focus to increase the coverage of the laser beam across the mask.

In one embodiment, the substrate may be pre-packaged using a suitable transparent packaging film such as polythene.

The wrapped packaging film holds the products tightly together. A patterning device may then pattern the transparent film with a non-transmissive laminate or layer such as ink, to produce a laminate contact mask which is also the packaging film.

Upon laser irradiation the patterned information is laser printed on to the substrate. Since the packaging material is transparent to the laser irradiation, the packaging material is still intact and can continue to be used as the packaging film. Alternatively, the transparent packaging film such as polythene can be pre-patterned in a web in film form and sectioned and wrapped around the substrate after the patterning operation and prior to printing.

In another exemplary embodiment of the invention, the non-transmissive laminate may be a sheet of thin absorbing or reflecting material such as, for example, copier or printer paper. The non-transmissive laminate is patterned using a patterning device such as a laser cutter, so that regions of the paper are removed thus forming transmissive areas in the otherwise non-transmissive laminate. The sections of non-transmissive laminates are then joined to a transmissive laminate such as a transparency or other clear film to form the laminate mask.

Alternatively the non-transmissive laminate, such as paper, may be pre-bonded to the transmissive laminate such as a transparency and then patterned by a device such as a laser etching system which can precisely and selectively vaporise the non-transmissive laminate in the desired printing pattern without detriment to the underlying transmissive layer.

A further use of the laminate mask is as a replacement to the spinning metallic stencil disc used in mask imaging laser printing systems. A disc-shaped laminate mask (such as the one shown in FIG. 3) is patterned with the desired character set around the circumference of the disc. The character set is patterned without tags. As the laminate mask is continuous in form without open spaces and tags, it can be spun at high rotational speeds without failure thereby increasing the printing speed of the laser printing system relative to known systems.

FIG. 8 shows an alternative embodiment of apparatus for making and method of using a mask according to as aspect of the invention. This embodiment is very attractive as it uses a paper printer as the framework, e.g. a Lexmark 1100. This uses a rail 20, which provides single axis movement in and out of the paper plane, and carries ink cartridge 30 or other device for patterning the transmissive layer 2 with a non transmissive layer 3. The cartridge 30 is secured to a belt which is in turn powered by a motor. The drive therefore moves the ink cartridge 30 across the dimension of a sheet of transmissive material 2. A carrier 40 holding an optic such as a mirror (not shown) is attached to and moves in unison with the ink cartridge 30 such that a beam of electromagnetic radiation 50, such as a laser beam, is turned down onto the laminate mask. So, as the printer prints the transmissive layer(s) the laser is also directed down through the laminate mask to mark, etch or print the surface of one or more objects 60.

Rollers 70 move the transmissive layer “paper” through the printer. In this embodiment, the rollers 70 also carry the sample 60 to be marked on a conveyor 80.

With modifications the printer could use a web of transmissive material to feed a continuous production line.

Referring to FIG. 9 of the drawings, marking apparatus according to yet another exemplary embodiment of the invention comprises a mask 100 which comprises a short cylinder or annulus and is fixed to a rotating axle 200, by means of a mask support 700. The circumference of the mask 100 is placed in close proximity to the material 103 to be marked. Such material being provided on a production line typically comprising a regularly spaced and continuous batch of parts, or a web of material or a tube or rod-like object or filamentary object such as an insulated, electrical wire.

A mirror 104 (or other beam-directing optical element) is provided within the annulus of the mask 100 such that a laser beam 105 from laser apparatus 106 is directed onto the mirror 104 and then to the inside face of the annular mask and propagates to the material 103 to be marked on the outside face of the annular mask 100.

The laser apparatus provides an intense beam of light, which may be pulsed or continuous. In this preferred embodiment, an ultraviolet laser may be used, but visible lasers may also be used. An ultraviolet laser providing 60 mJ at a wavelength of 355 nm, at a repetition rate of 25 Hz is suitable for use in the described embodiment.

Referring to FIG. 10 of the drawings, the moving material or materials 103 is or are in contact with an encoder wheel 110 such that, as the material moves, the encoder wheel 110 turns. A mechanical linkage 111 connects the encoder wheel 110 to the annular mask 100 such that the annular mask 110 rotates. Therefore, simple mechanical linkages enable a circular motion of the annular mask that is synchronous with the moving material to be marked, which is located beneath the mask 100.

Pulley guides 112 are provided to ensure that the material 103 remains in-line with the data string (not shown)on the mask 100 and directly below the mask 100 such that the laser beam 105 deflects from the mirror 104 through the mask 100 and onto the material to be marked 3 at a marking point 113.

FIG. 11 shows an example of an annular mask 100 with a data string 120 to be marked on the circumference of the annulus. The mirror 104 deflects the laser beam 105 through the mask 100 and onto the material to be marked 103. The position and frequency of the data string 120 can be varied to change the pitch and frequency of the data string markings on the material to be marked 103. The diameter or circumferential length of the annulus mask can be adjusted to suit any particular application.

The mask can be made from a variety of suitable materials which can withstand the necessary exposure to the laser beam.

A laminate mask has been successfully employed with 19 mixed, alphanumeric characters, the data string stretching over 35 mm. The data string was provided only once along the circumference of 205 mm. Therefore the markings produced on the material, an electrical insulated wire, were pitched at 205 mm.

A paper mask has also been used with 3 mm diameter circular symbols pitched every 13 mm all along the mask circumference. This generated 3 mm, circular symbols marked with a pitch of 13 mm continuously on the material as it passed beneath the annular mask.

In addition, most metallic and some plastics materials could be used as the annular mask material.

These aspects of the invention can be used in a variety of continuous printing or marking applications, such as for printing manufacturers' part numbers onto insulated electrical wires and cables.

Embodiments of the invention have been described herein by way of example only. Various modifications and varieties are envisaged and will be apparent to a person skilled in the art, without departing from the scope of the invention as defined by the appended claims.

1. A mask for printing, marking or etching a surface using electromagnetic radiation, such as a laser or the like, or otherwise exposing one or more selected areas of a surface for treatment, the mask comprising a first layer of substantially radiation transmissive material and a second layer of material which is substantially non-transmissive to radiation, said non-transmissive layer being applied on or joined to said transmissive layer so as to partially cover a surface thereof, an uncovered portion of said transmissive layer being in the shape of an element, such as a character, symbol or shape, to be printed, marked, etched or otherwise provided on said surface.

2. A mask according to claim 1, wherein said transmissive layer is substantially transparent.

3. A mask according to claim 1, wherein said transmissive material is a printer transparency, typically of polyester film, polythene film or other plastics film, or acetate or cellulose film.

4. A mask according to claim 1, wherein said mask is a rotatable disc of transmissive material, said non-transmissive material being applied thereon or joined thereto, so as to partially cover the surface thereof, a plurality of uncovered portions of said transmissive layer being in the shape of elements to be printed, marked, etched or otherwise provided on said surface.

5. A mask according to claim 4, wherein said uncovered portions are located at or adjacent the circumference of said disc.

6. A mask according to claim 1, wherein said mask is in the form of a continuous closed loop.

7. A mask according to claim 1, wherein said mask is an elongate strip having along its length a plurality of uncovered portions in the shape of elements to be printed, marked or etched on said surface.

8. A mask according to claim 1, wherein said non-transmissive layer is an absorbing or reflecting material such as ink or toner, selectively applied to said transmissive layer.

9. A mask according to claim 1, wherein said non-transmissive layer is a sheet of absorbing or reflecting material, such as paper, bonded to said transmissive layer.

10. A mask for printing, etching or marking a surface using electromagnetic radiation, such as a laser or the like, or otherwise exposing one or more selected areas of a surface for treatment, the mask comprising a first layer of substantially clear or transparent material and a second layer of material which is substantially non-transmissive to radiation, said non-transmissive layer having a substantially transmissive portion in the shape of an element, such as a shape, character or symbol to be printed, etched, marked or otherwise provided on said surface.

11. A mask according to claim 10, wherein said transmissive and non-transmissive layers are in contact or very close proximity with each other, when in use.

12. A mask according to claim 10, wherein said transmissive and non-transmissive layers are spatially separated from each other, when in use.

13. A mask according to claim 10, wherein said transmissive material is a printer transparency, typically of polyester film, polythene film or other plastics film, or acetate or cellulose film.

14. A mask according to claim 10, wherein said non-transmissive layer is an absorbing or reflecting material, such as ink or toner, selectively applied to said transmissive layer.

15. A mask according to claim 10, wherein said non-transmissive layer is a sheet of absorbing or reflecting material, such as paper.

16. A mask for printing, etching or marking a surface using electromagnetic radiation, such as a laser or the like, or otherwise exposing one or more selected areas of a surface for treatment, the mask comprising a first layer of substantially radiation transmissive material, and a second layer comprising at least two portions which are transmissive to radiation, one of said radiation transmissive portions being relatively less transmissive to radiation than the other portion.

17. A mask according to claim 17, wherein said second layer comprises a plurality of portions of varying degrees of transmissivity.

18. A mask according to claim 16, wherein the second layer comprises one or more coloured inks or toners selectively applied to said first layer.

19. A mask for printing, etching or marking a surface using electromagnetic radiation, such as a laser or the like, or otherwise exposing one or more selected areas of a surface for treatment, the mask comprising a layer of substantially radiation transmissive material, a portion of which has been subjected to spatial modification to reduce the transmissivity thereof.

20. A method of making a mask for printing, etching or marking a surface using electromagnetic radiation such as a laser or the like, or otherwise exposing one or more selected areas of a surface for treatment, the method comprising the steps of spatially modifying one or more portions of a layer of substantially radiation transmissive material to reduce the transmissivity thereof.

21. A method according to claim 20, comprising exposing said one or more portions of said radiation transmissive layer to electromagnetic radiation, such as a laser, so that a portion of said incident radiation is absorbed by said transmissive layer, creating a physical change in the properties of said one or more portions of said layer.

22. A mask according to claim 1, wherein said element to be printed, marked, etched or otherwise provided on said surface is one or more of graphics, alphanumeric characters, symbols, patterns, numbers, bar codes and pictographic symbols.

23. Apparatus for printing, etching or marking a surface, or otherwise exposing one or more areas of a surface for treatment, the apparatus including a mask according to claim 1.

24. Apparatus for printing, etching or marking a surface, or otherwise exposing one or more areas of a surface for treatment, the apparatus comprising a source of electromagnetic radiation and a mask according to claim 1.

25. Apparatus according to claim 26, wherein said source of electromagnetic radiation is a laser.

26. Apparatus according to claim 27, wherein the laser is a frequency-tripled Nd:YAG laser.

27. Apparatus according to claim 26, wherein said laser is pulsed.

28. Apparatus according to claim 29, wherein said laser is actuated in pulses of around 5 ns, at a pulse repetition frequency of around 25 Hz and a pulse energy of around 50 mJ.

29. Apparatus according to claim 25, including a generally circular, rotatable table for receiving objects to be printed, marked, etched, or otherwise treated, said mask being generally disc-shaped rotatable and positioned between said table and said source of electromagnetic radiation, when in use.

30. Apparatus according to claim 25, wherein said mask is in the form of a continuous closed loop and rotatable, and said source of electromagnetic radiation is located within the ring-like mask, the objects to be printed, etched or marked being located outside said ring-like mask, such that, in use, the mask is between the source of electromagnetic radiation and said objects.

31. Apparatus according to claim 25, wherein said mask comprises an elongate strip which is wound on a first spool and the apparatus includes a second spool, the mask being fed, in use, between objects to be printed and said source of electromagnetic radiation from the first spool to the second spool.

32. Apparatus according to claim 25, wherein beam expansion optics, such as a telescope or diverging optical lens, are located between said source of electromagnetic radiation and said mask.

33. A method of making a mask for use in printing, marking or etching a surface using electromagnetic radiation, or otherwise exposing one or more selected areas of a surface for treatment, the method comprising the steps of providing a first layer of substantially radiation-transmissive material and applying thereon or joining thereto a second layer of material which is relatively less radiation transmissive than said first layer, such that said less transmissive layer partially covers said transmissive layer, an uncovered portion of said transmissive layer being in the shape of an element, such as a shape, character or symbol, to be printed, marked or etched or otherwise provided on said surface.

34. A method according to claim 36, wherein said transmissive layer is substantially transparent.

35. A method according to claim 36, wherein said transmissive layer is a printer transparency, typically of polyester film, polythene film or other plastics film, or acetate or cellulose film.

36. A method according to claim 36, wherein said non-transmissive layer is printed onto the transmissive layer.

37. A method according to claim 39, wherein said non-transmissive layer is ink applied to a surface of said transmissive layer.

38. A method according to claim 39, wherein said non-transmissive layer is toner applied to a surface of said transmissive layer.

39. A method according to claim 36, wherein said transmissive layer is at least partially covered with a substantially transparent packaging film, prior to application of said non-transmissive layer.

40. A method according to claim 36, including the steps of making said non-transmissive layer by applying an absorbing or reflecting material to a transparent packaging film, and at least partially wrapping said packaging film around an object, the surface of which is to be printed, marked or etched.

41. A method according to claim 36, including the step of bonding or otherwise joining a sheet of absorbing or reflecting material which has a transmissive portion in the shape of the element to be printed, marked or etched, to said transmissive layer.

42. A method according to claim 43, wherein said absorbing or reflecting material is paper.

43. A method according to claim 43, wherein said transmissive portion of said non-transmissive material is formed using a laser cutter.

44. A method according to claim 36, including the step of removing a portion of said reflecting or absorbing material, joining or applying the non-transmissive material to said transmissive layer and subsequently to form said transmissive portion in the shape of said element to be printed, marked, etched or otherwise provided on said surface.

45. A method according to claim 45, wherein said portion of said non-transmissive material is removed using a laser etching system.

46. A mask for use in printing, marking or etching a surface using electromagnetic radiation, or otherwise exposing one or more selected areas of a surface for treatment, the mask being in the form of a continuous closed loop, such as an annular or hollow cylindrical body.

47. A mask according to claim 50, comprising a first layer of substantially radiation transmissive material and a second layer of material which is substantially non-transmissive to radiation, said non-transmissive layer being applied on or bonded to the transmissive layer so as to partially cover a surface thereof, an uncovered portion of the transmissive layer providing a window in the shape of an element, such as a character, symbol or shape, to be printed, marked, etched or otherwise provided on the surface.

48. A mask according to claim 50, having a central axis about which it can be rotated.

49. Apparatus for printing, marking or etching a surface comprising a mask according to claim 50, apparatus for rotating the mask, support apparatus for supporting an object to be printed, marked or etched, and apparatus for directing electromagnetic radiation through the mask and onto the surface of the object to be printed, marked or etched when the object is supported by the support apparatus.

50. Apparatus according to claim 53, wherein said electromagnetic radiation comprises laser radiation.

51. Apparatus according to claim 53, comprising a beam-turning optical element, such as a mirror, arranged to direct the electromagnetic radiation through the mask and onto the surface of the object to be marked.

52. Apparatus according to claim 53, including transporting apparatus for transporting one or more objects to be marked to a position in which said marking is to take place, and apparatus for synchronising movement of the transporting apparatus with rotation of the mask.

53. Apparatus according to claim 56, wherein said transporting apparatus is linked to the mask via a mechanical linkage.

54. Apparatus according to claim 56, wherein said transporting apparatus is linked to the mask via an electronic servo-driven linkage.

55. Apparatus according to claim 56, wherein said mask is a rotating mechanism in contact, whether directly or indirectly, with the transporting apparatus.

56. A method for marking a surface, the method comprising the steps of providing a mask in the form of a continuous closed loop, rotating the mask and directing electromagnetic radiation through the mask onto the surface to be marked.

57. Apparatus for printing, marking or etching a surface, the apparatus comprising a mask, a transporter for transporting one or more objects to be printed on, marked or etched to a position in which said printing, marking or etching is to take place, motive apparatus for moving the mask in synchronism with said transporter, and apparatus for directing electromagnetic radiation through the mask and onto the surface of the object to be printed on, marked or etched at said position in which said printing, marking or etching is to take place.

58. A method of printing, marking or etching a surface, the method comprising the steps of providing a mask, transporting one or more objects to be printed on, marked or etched to a position in which said printing, marking or etching is to take place, moving said mask in synchronism with the objects being transported, and directing electromagnetic radiation through the mask and onto the surface of the object to be printed on, marked or etched at said position in which said printing, marking or etching is to take place.

59. An apparatus according to claim 61, wherein the mask is in the form of an elongate tape moving in synchronism with the transport means, for example, between two spools or the like.
